(19) United States
(12) Patent Application Publication
(10) Pub. No.: US 2026/0223471 A1
(43) Pub. Date: Jul. 30, 2026

(54) SOLID-STATE IMAGING ELEMENT, MANUFACTURING METHOD THEREOF, AND ELECTRONIC DEVICE

(71) Applicant: SONY SEMICONDUCTOR SOLUTIONS CORPORATION, KANAGAWA (JP)

(72) Inventor: MUTSUO UEHARA, KANAGAWA (JP)

(21) Appl. No.: 19/148,333

(22) PCT Filed: Jan. 18, 2024
(86) PCT No.: PCT/JP2024/001197

§ 371 Date: Jul. 16, 2025

(30) Foreign Application Priority Data
Jan. 30, 2023 (JP) 2023-012038

(51) Int. Cl. H10F 39/00

(52) U.S. Cl. CPC H10F 39/807; H10F 39/014; H10F 39/802; H10F 39/811

(57) ABSTRACT

The present disclosure relates to a solid-state imaging element, a manufacturing method thereof, and an electronic device that enables the improvement of the characteristics of a pixel. A solid-state imaging element includes a semiconductor substrate having a first surface that serves as a light incident surface and a second surface that is on an opposite side the first surface, a first photoelectric conversion unit provided in the semiconductor substrate, a second photoelectric conversion unit provided adjacent to the first photoelectric conversion unit, and a pixel isolation part provided between the first photoelectric conversion unit and the second photoelectric conversion unit. Then, the pixel isolation part has a laminated structure in which a first layer, a second layer, and a third layer are stacked sequentially from the first surface side in a cross-sectional view, and the second layer has a shape in which width thereof is different between the first layer side and the third layer side in a cross-sectional view. Further, the second layer is formed in a self-aligned manner at a predetermined position in an in-plane direction and a depth direction of the semiconductor substrate by utilizing a step portion formed in a middle of a trench provided in the semiconductor substrate. The present technology can be applied to, for example, a stacked type CMOS image sensor.

### TECHNICAL FIELD

The present disclosure relates to a solid-state imaging element, a manufacturing method thereof, and an electronic device, and particularly to a solid-state imaging element, a manufacturing method thereof, and an electronic device configured to enable the improvement of the characteristics of pixels.

### BACKGROUND ART

Conventionally, a solid-state imaging element such as a stacked CMOS (complementary metal-oxide-semiconductor) image sensor has adopted a structure in which isolation parts are provided between respective pixels in order to suppress color mixture between adjacent pixels. Proposed is, for example, an isolation part having a structure in which polysilicon is embedded in the entire trench processed from the front surface side of a semiconductor layer, or, for example, an isolation part having a two-layer structure in which polysilicon is embedded from the front surface side of the trench processed from the front surface side of a semiconductor layer and in which an insulator (for example, an oxide such as SiO2) is embedded from the rear surface side of the semiconductor layer.

Further, PTL 1 discloses a structure of an isolation part configured such that FDTI (front deep trench isolation) formed based on a trench processed from the front surface side of a semiconductor layer and RDTI (rear deep trench isolation) formed based on a trench processed from the rear surface side of the semiconductor layer are in direct contact with each other.

### CITATION LIST

### Patent Literature

[PTL 1] JP No. 2021-166304A

### SUMMARY

### Technical Problem

However, in the structure of the isolation part disclosed in PTL 1, there have been some cases where the positions where FDTI and RDTI are provided are shifted in the in-plane direction. Further, in the above-described two-layer structure of the polysilicon and the insulator, there has been a case where a variation is caused in the depth direction of the boundary between these layers. In this way, there is a concern that the shift or variation occurring in the isolation part adversely affects the characteristics of the pixels.

The present disclosure has been made in view of such situations, and is directed to enable the improvement of the characteristics of the pixel.

### Solution to Problem

A solid-state image sensor of one aspect of the present disclosure includes a semiconductor substrate having a first surface that serves as a light incident surface and a second surface on an opposite side to the first surface, a first photoelectric conversion unit provided in the semiconductor substrate, a second photoelectric conversion unit provided adjacent to the first photoelectric conversion unit, and a pixel isolation part provided between the first photoelectric conversion unit and the second photoelectric conversion unit, in which the pixel isolation part has a stacked structure in which a first layer, a second layer, and a third layer are stacked sequentially from the first surface side in a cross-sectional view, the second layer has a shape in which width thereof is different between the first layer side and the third layer side in a cross-sectional view.

A manufacturing method of one aspect of the present disclosure is a method for manufacturing a solid-state imaging element, the element including a semiconductor substrate having a first surface that serves as a light incident surface and a second surface on an opposite side to the first surface, a first photoelectric conversion unit provided in the semiconductor substrate, a second photoelectric conversion unit provided adjacent to the first photoelectric conversion unit, and a pixel isolation part provided between the first photoelectric conversion unit and the second photoelectric conversion unit, in which the pixel isolation part has a stacked structure in which a first layer, a second layer, and a third layer are stacked sequentially from the first surface side in a cross-sectional view, and the second layer has a shape in which width thereof is different between the first layer side and the third layer side in a cross-sectional view, and the method including forming the second layer in a self-aligned manner at a predetermined position in an in-plane direction and a depth direction of the semiconductor substrate using a step portion formed in the middle of a trench provided in the semiconductor substrate.

An electronic device of one aspect of the present disclosure includes a solid-state imaging element including a semiconductor substrate having a first surface that serves as a light incident surface and a second surface on an opposite side to the first surface, a first photoelectric conversion unit provided in the semiconductor substrate, a second photoelectric conversion unit provided adjacent to the first photoelectric conversion unit, and a pixel isolation part provided between the first photoelectric conversion unit and the second photoelectric conversion unit, in which the pixel isolation part has a stacked structure in which a first layer, a second layer, and a third layer are stacked sequentially from the first surface side in a cross-sectional view, and the second layer has a shape in which width thereof is different between the first layer side and the third layer side in a cross-sectional view.

In one aspect of the present disclosure, a semiconductor substrate has a first surface that serves as a light incident surface and a second surface on an opposite side to the first surface, a first photoelectric conversion unit is provided in the semiconductor substrate, a second photoelectric conversion unit is provided adjacent to the first photoelectric conversion unit, and a pixel isolation part is provided between the first photoelectric conversion unit and the second photoelectric conversion unit. Then, the pixel isolation part has a stacked structure in which a first layer, a second layer, and a third layer are stacked sequentially from the first surface side in a cross-sectional view, and the second layer has a shape in which width thereof is different between the first layer side and the third layer side in a cross-sectional view. Further, the second layer is formed in a self-aligned manner at a predetermined position in the in-plane direction and the depth direction of the semiconductor substrate by utilizing a step portion formed in the middle of a trench provided in the semiconductor substrate.

### BRIEF DESCRIPTION OF DRAWINGS

FIG. 1 is a block diagram illustrating a configuration example of an embodiment of an imaging element to which the present technology is applied.

FIG. 2 is a diagram illustrating a planar configuration example of pixels.

FIG. 3 is a diagram for illustrating first to third steps of the method for manufacturing an imaging element.

FIG. 4 is a diagram for illustrating forth to sixth steps of the method for manufacturing an imaging element.

FIG. 5 is a diagram for illustrating seventh to ninth steps of the method for manufacturing an imaging element.

FIG. 6 is a diagram for illustrating tenth to twelfth steps of the method for manufacturing an imaging element.

FIG. 7 is a diagram for illustrating 13th to 15th steps of the method for manufacturing an imaging element.

FIG. 8 is a diagram for illustrating 16th to 18th steps of the method for manufacturing an imaging element.

FIG. 9 is a block diagram illustrating a configuration example of an imaging device.

FIG. 10 is a diagram for illustrating usage examples using an image sensor.

### DESCRIPTION OF EMBODIMENTS

Hereinafter, specific embodiments to which the present technology is applied will be described in details with reference to the drawings.

### <Configuration Example of Imaging Element>

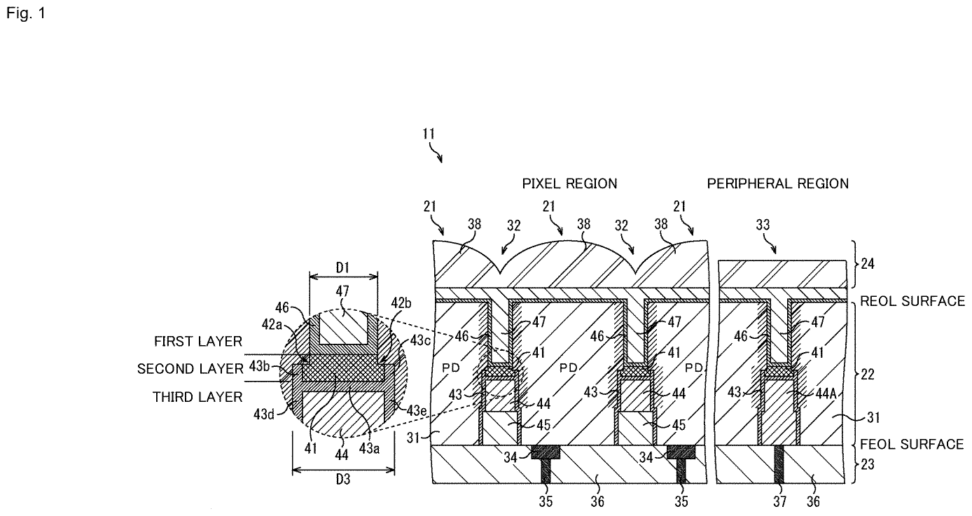

FIG. 1 is a diagram showing a configuration example of an embodiment of an imaging element to which the present technique is applied.

As shown in FIG. 1, an imaging element 11 is configured such that a pixel region in which a plurality of pixels 21 are arranged in an array, and a peripheral region surrounding the periphery of the pixel region are provided. Further, the imaging element 11 is configured such that a wiring layer 23 is stacked on a surface (hereinafter referred to as an FEOL surface) of a sensor layer 22 on which a photoelectric conversion unit PD is provided for each pixel 21, and an on-chip lens layer 24 is stacked on the rear surface (hereinafter referred to as a REOL surface) side of the sensor layer 22. Incidentally, the REOL surface is a first surface that serves as a light incident surface of a semiconductor substrate 31, and the FEOL surface is a second surface of the semiconductor substrate 31 that is opposite to the REOL surface.

The sensor layer 22 is configured, for example, by ion-implanting an N-type impurity into the semiconductor substrate 31 provided with a P-type well, thereby forming a photoelectric conversion unit PD. Then, on the semiconductor substrate 31, a pixel isolation part 32 is provided between the photoelectric conversion units PD so as to surround the respective photoelectric conversion units PD and isolate the pixels 21 from each other. Further, an isolation part 33 is also provided on the semiconductor substrate 31 that is a peripheral region of the sensor layer 22. In the semiconductor substrate 31 shown in FIG. 1, a region hatched at a narrow pitch so as to be in contact with the side surfaces of the pixel isolation part 32 and isolation part 33 indicates that the side surfaces of the trench are doped by, for example, adding an impurity such as boron (B).

The wiring layer 23 is configured by providing a gate electrode 34 of a transistor that drives the pixel 21, a contact electrode 35 electrically connected to the gate electrode 34, and a wire (not shown) in the insulating film 36. Further, in the peripheral region of the wiring layer 23, a contact electrode 37 electrically connected to the polysilicon layer 44A of the isolation part 33 is provided in the insulating film 36.

The on-chip lens layer 24 is stacked on the REOL surface of the semiconductor substrate 31 via a high-dielectric-constant film 46 and a second insulating layer 47, and is configured such that a microlens 38 that condenses light for each pixel 21 is arranged in the pixel region. Further, in the peripheral region of the on-chip lens layer 24, a transparent material constituting the microlens 38 is provided flat.

The pixel isolation part 32 is configured by providing a connection layer 41 made of a semiconductor connecting the semiconductor substrates 31 on both sides of a trench in the middle of the trench provided so as to penetrate the semiconductor substrate 31. For example, the connection layer 41 is formed of a semiconductor (single crystal silicon of P type identical to that of the well of the pixel 21) epitaxially grown from both of a connection part 42a with one semiconductor substrate 31 isolated by the pixel isolation part 32 and a connection part 42b with the other semiconductor substrate 31 isolated by the pixel isolation part 32, and electrically connects the connecting part 42a and the connecting part 42b. Incidentally, the connection layer 41 is not limited to being formed by epitaxial growth so long as it can be formed of a material that can electrically connect the well of one pixel 21 to the well of the other pixel 21 and can be formed in a self-aligned manner by utilizing the connection part 42a and the connection part 42b.

Further, the pixel isolation part 32 is configured such that an insulating film 43 is provided so as to cover the FEOL surface side surface of the connection layer 41 and both side surfaces of the trench which is closer to the FEOL surface side than the connection part 42a and the connection part 42b, and a polysilicon layer 44 and a first insulating layer 45 are embedded in the inside of the trench via the insulating film 43. That is, the polysilicon layer 44 is provided on the FEOL surface side of the connection layer 41 via the insulating film 43, and the first insulating layer 45 is provided on the FEOL surface side of the polysilicon layer 44. Further, as shown in an enlarged view on the left side in FIG. 1, the insulating film 43 is deposited such that an insulating film 43a is provided between the connection layer 41 and the polysilicon layer 44, an insulating film 43b and an insulating film 43c are provided on both side surfaces of the connection layer 41, and an insulating film 43c and an insulating film 43d are provided on both side surfaces of the polysilicon layer 44.

Further, the pixel isolation part 32 is configured such that a high-dielectric-constant film 46 is provided so as to cover a surface on the REOL surface side of the connection layer 41 and both side surfaces of the trench which is closer to the REOL surface side than the connection layer 41, and a second insulating layer 47 is embedded in the inside of the trench via the high-dielectric-constant film 46. Further, the high-dielectric-constant film 46 is stacked on the REOL surface of the semiconductor substrate 31, and the second insulating layer 47 is stacked on the REOL surface of the semiconductor substrate 31 via the high-dielectric-constant film 46.

Here, as shown on the left side of FIG. 1, the pixel isolation part 32 has a stacked structure in which the region provided with the connection layer 41 is defined as a second layer, the REOL surface side from the connection layer 41 as a first layer, and the FEOL surface side from the connection layer 41 as a third layer. Then, the pixel isolation part 32 has a shape in which a step is provided in the width of the connection layer 41 in the second layer, and is formed in a shape in which the width is different between the first layer side and the third layer side in a cross-sectional view. That is, the pixel isolation part 32 is formed in a convex shape in cross section so that the REOL surface side of the connection layer 41 becomes narrow, and the FEOL surface side of the connection layer 41 becomes wide. Accordingly, the pixel isolation part 32 is configured so that a width D1 of the first layer that is the REOL surface side is narrow and a width D3 of the third layer that is the FEOL surface side is wide.

Further, the semiconductor substrate 31 can be formed with a thickness up to 6 μm, the pixel isolation part 32 can be formed so that the first layer is provided at a depth within the range of 0.2 to 6 range μm from the FEOL surface, the second layer is provided with a width of 0.1 μm or more at any position at a depth within the range of 0.1 to 6 μm from the FEOL surface, and the third layer is provided at a depth within the range of 0.1 to 1 μm from the FEOL surface.

The isolation part 33 is configured similarly to the pixel isolation part 32, but is configured differently from the pixel isolation part 32 in that a polysilicon layer 44A is embedded in a region where the first insulating layer 45 and the polysilicon layer 44 are embedded in the pixel isolation part 32. Then, a contact electrode 37 is connected to the polysilicon layer 44A, so that a bias voltage can be applied through the contact electrode 37.

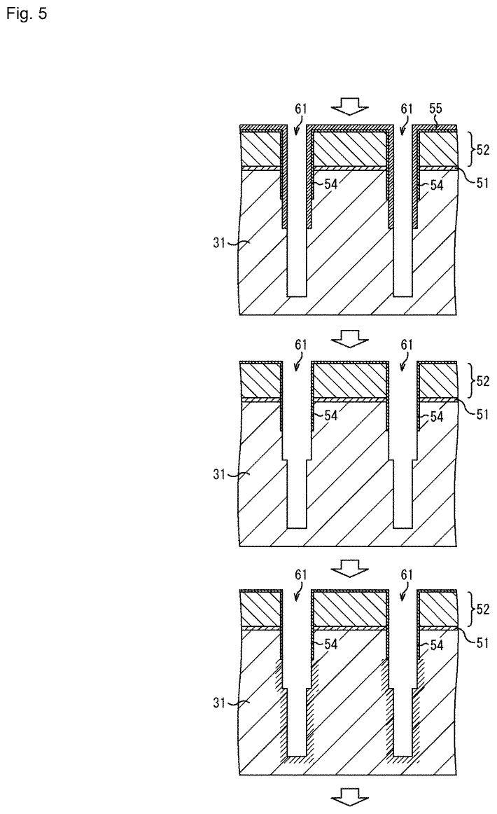

The imaging element 11 is configured as described up to this point, and the connection layer 41 is formed of a material (for example, single crystal silicon formed by epitaxial growth) that can be formed in self-alignment based on the connection part 42a and the connection part 42b present on both sides in the middle of the trench provided so as to penetrate the silicon substrate that is the semiconductor substrate 31. As a result, the pixel isolation part 32 can be formed more accurately. That is, alignment for forming the connection layer 41 is not required, and the connection layer 41 is formed in a self-aligned manner at a predetermined position in the in-plane direction and the depth direction of the semiconductor substrate 31 by utilizing the step portion (see the second stage in FIG. 5) formed in the middle of the trench.

For example, in the conventional isolation part as described above, there is a concern that the characteristics of the pixels are degraded due to a structure in which shift or variation occurs. On the other hand, in the imaging element 11, the first layer including the second insulating layer 47 embedded from the REOL surface side of the semiconductor substrate 31 and the third layer including the first insulating layer 45 and the polysilicon layer 44 embedded from the FEOL surface side of the semiconductor substrate 31 do not shift in the in-plane direction and no variation is caused in the depth direction of the second layer provided between the first layer and the third layer. For this reason, the pixel isolation part 32 can be formed with high accuracy. Accordingly, the imaging element 11 can avoid the occurrence of such shift or variation that adversely affects the characteristics of the pixels, and consequently, the characteristics of the pixels 21 can be improved.

Also, the imaging element 11 has a configuration in which the polysilicon layer 44 is provided on a part of the FEOL surface side, and a second insulating layer 47 is embedded on the REOL surface side via the high-dielectric-constant film 46. As a result, for example, as compared with a configuration in which polysilicon is embedded in the entire isolation part, it is possible to avoid a decrease in quantum efficiency Qe due to light absorption and suppress deterioration in dark current.

Furthermore, the imaging element 11 can be configured, for example, to eliminate the need for a well tap provided for connecting the wells by configuring the pixel isolation part 32 so that the wells of the adjacent pixels 21 are electrically connected to each other by the conductive connection layer 41.

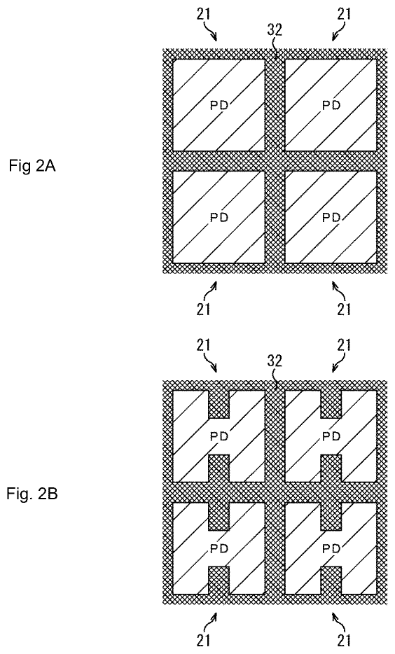

FIG. 2 shows an example of a planar configuration of four pixels 21 arranged in 2×2.

As shown in FIG. 2A, the pixels 21 may be configured so as to have a rectangular shape in a plan view. Then, the pixel isolation part 32 is provided so as to surround each of the pixels 21.

As shown in FIG. 2B, the pixel 21 may be configured to have a shape in which, in a plan view, inwardly facing cut portions are provided on two opposing sides (upper and lower sides in the illustrated example) of a rectangular shape. Then, the pixel isolation part 32 is provided so as to surround each pixel 21, and is also provided in the cut portion of each pixel 21.

It is naturally understood that the pixel 21 may adopt a planar shape other than the shape as shown in FIG. 2.

### [Method for Manufacturing Imaging Element]

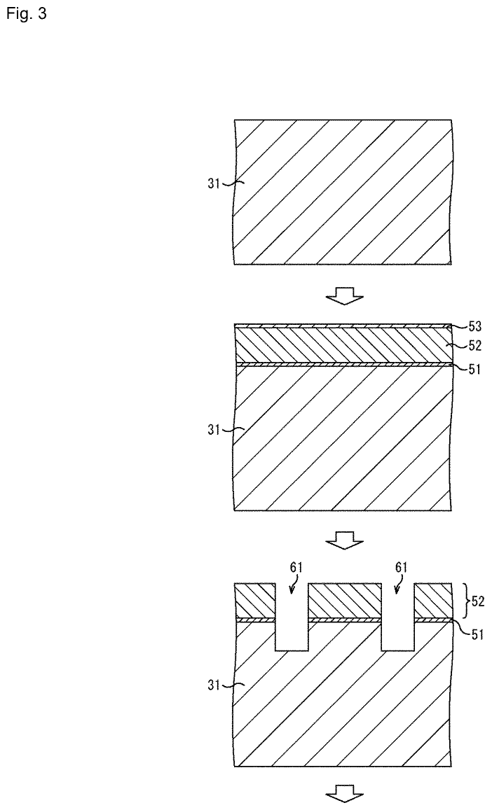

Referring to FIGS. 3 to 8, the steps of forming the pixel isolation part 32 in the method for manufacturing the imaging element 11 will be described.

In the first step, as shown in the first stage in FIG. 3, a semiconductor substrate 31 is prepared which has been processed to have a predetermined thickness (for example, 6 μm) or more.

In the second step, as shown in the second stage in FIG. 3, a SiN film 51, a SiO layer 52, and a polysilicon film 53 for use as a hard mask are stacked with respect to the surface of the semiconductor substrate 31.

In the third step, as shown in the third stage in FIG. 3, the SiN film 51 and the SiO layer 52 are processed so that a region where the pixel isolation part 32 is to be formed is opened, and the semiconductor substrate 31 is dug shallow using the SiN film 51 and the SiO layer 52 as a hard mask, thereby performing processing to form the trench 61. For example, in the third step, the depth of the trench 61 is set according to the distance from the FEOL surface of the region where the first insulating layer 45 shown in FIG. 1 is embedded.

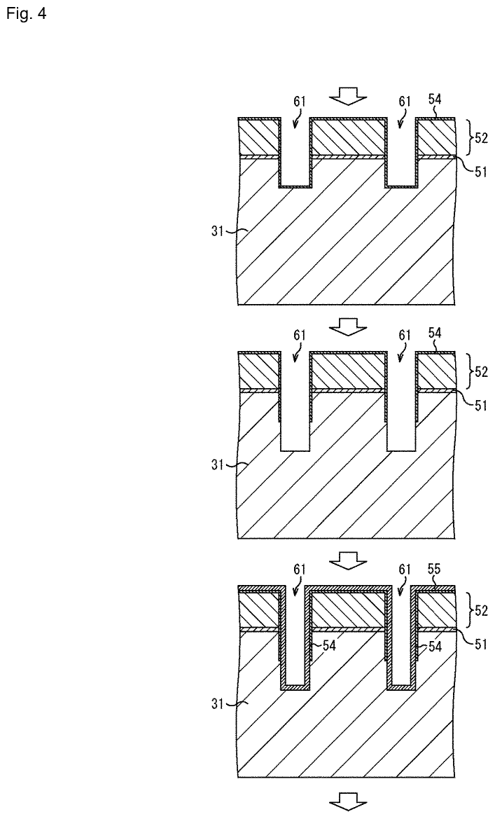

In the fourth step, the SiN film 54 is deposited as shown in the first stage in FIG. 4. As shown, the SiN film 54 is provided so as to cover the bottom surface and side surfaces of the trench 61 and the surface of the SiO layer 52.

In the fifth step, as shown in the second stage in FIG. 4, the SiN film 54 on the bottom surface of the trench 61 is removed, and the semiconductor substrate 31 on the bottom surface thereof is dug, thereby performing processing to increase the depth of the trench 61. For example, in the fifth step, the depth of the trench 61 is set in accordance with the distance from the FEOL surface in the region where the polysilicon layer 44 shown in FIG. 1 is embedded.

In the sixth step, an SiO film 55 is deposited as shown in the third stage in FIG. 4. As shown, the SiO film 55 is provided so as to cover the bottom surface and the side surfaces of the trench 61, and the surface of the SiO layer 52 via the SiN film 54.

In the seventh step, as shown in the first stage in FIG. 5, the SiO film 55 on the bottom surface of the trench 61 is removed, and the semiconductor substrate 31 on the bottom surface is dug, thereby performing processing to increase the depth of the trench 61. For example, in the seventh step, the depth of the trench 61 is set so as to be a depth equal to or greater than the thickness of the sensor layer 22 shown in FIG. 1.

In the eighth step, the SiO film 55 is removed as shown in the second stage in FIG. 5. As a result, a step portion having a shape in which a step is provided in the middle of the trench 61 is formed.

In the ninth step, as shown in the third stage in FIG. 5, for example, processing of ion-implanting boron into the side surface of the semiconductor substrate 31 in the region where the SiN film 54 is not deposited in the side surface of the trench 61, thereby doping the side surface of the trench 61 is performed.

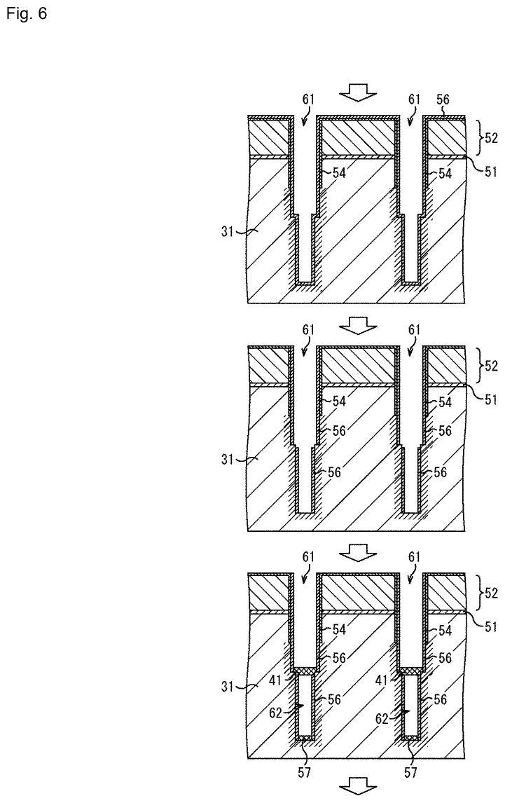

In the tenth step, an SiO film 56 is deposited as shown in the first stage in FIG. 6. As shown, the SiO film 56 is provided so as to cover the bottom surface and the side surfaces of the trench 61 and so as to cover the surface of the SiO layer 52 via the SiN film 54.

In the eleventh step, as shown in the second stage in FIG. 6, the SiO film 56 is etched back. As a result, the SiO film 56 stacked on the step portion formed in the middle of the trench 61 is removed, and the semiconductor substrate 31 is exposed at a portion that becomes the connection parts 42a and 42b (see FIG. 1). At the same time, the SiO film 56 stacked on the bottom surface of the trench 61 is removed to expose the semiconductor substrate 31, and the SiO film 56 stacked on the surface of the SiO layer 52 is also removed.

In the twelfth step, as shown in the third stage in FIG. 6, a semiconductor is epitaxially grown from a portion where the semiconductor substrate 31 is exposed at the step portion and the bottom surface of the trench 61. As a result, a connection layer 41 is formed at the step portion formed in the middle of the trench 61, and a bottom surface layer 57 is formed at the bottom surface of the trench 61. At this time, the space sandwiched between the connection layer 41 and the bottom surface layer 57 is a cavity 62 in which nothing is embedded.

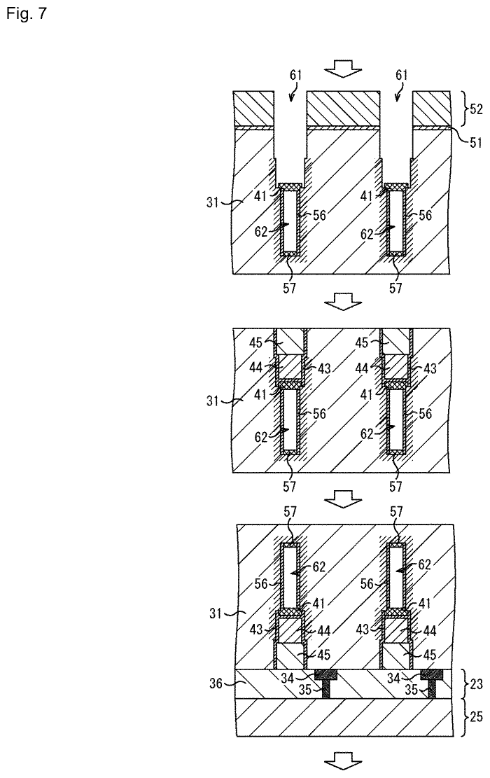

In the thirteenth step, as shown in the first stage in FIG. 7, the SiO film 56 in a region other than the cavity 62 is removed, and the SiN film 54 is removed.

In the fourteenth step, as shown in the second stage in FIG. 7, an insulating film 43 is deposited on the side surfaces of the trench 61 and the surface of the connection layer 41, and the polysilicon layer 44 and the first insulating layer 45 are embedded in the inside of the trench 61. Further, the SiN film 51 and the SiO layer 52 used as a hard mask are removed.

In the fifteenth step, as shown in the third stage in FIG. 7, a wiring layer 23 is stacked on the surface of the semiconductor substrate 31, and further, a logic substrate 25 provided with a logic circuit is bonded via the wiring layer 23, followed by reversal in order to perform a step targeted for the rear surface side of the semiconductor substrate 31.

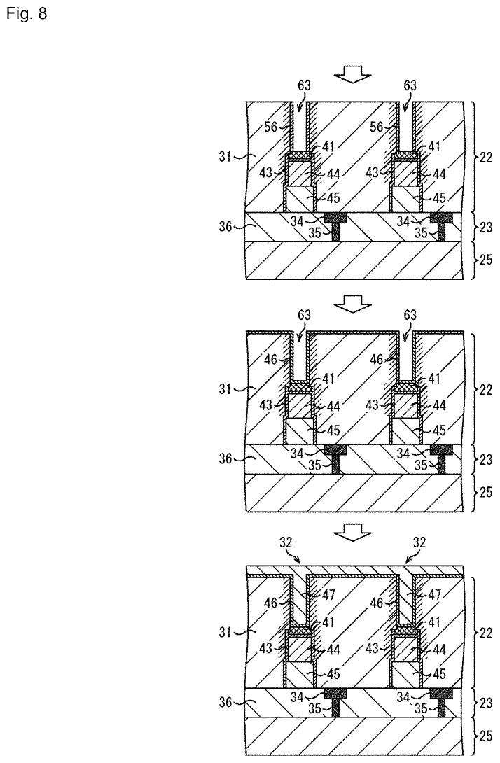

In the sixteenth step, as shown in the first stage in FIG. 8, the semiconductor substrate 31 is subjected to processing of thinning until the thickness becomes the thickness of the sensor layer 22. As a result, the bottom surface layer 57 is removed and the rear surface side of the cavity 62 is opened, thereby providing a trench 63.

In the seventeenth step, as shown in the second stage in FIG. 8, after the SiO film 56 on the side surface of the trench 63 is removed, and then, a high-dielectric-constant film 46 is deposited using, for example, aluminum oxide (AlO) or hafnium oxide (Hf). As shown, the high-dielectric-constant film 46 is provided so as to cover the bottom surface and the side surfaces of the trench 63 and the rear surface of the semiconductor substrate 31.

In the eighteenth step, a second insulating layer 47 is formed as shown in the third stage in FIG. 8. As shown, the second insulating layer 47 is embedded in the inside of the trench 63 via the high-dielectric-constant film 46, and is provided so as to cover the rear surface of the semiconductor substrate 31 via the high-dielectric-constant film 46.

The sensor layer 22 can be formed on the pixel isolation part 32 by the above-described steps. For example, in the pixel isolation part 32, the connection layer 41 can be formed in a self-aligned manner at a predetermined position in the in-plane direction and the depth direction of the semiconductor substrate 31 (see the third stage in FIG. 6) by utilizing the step portion (see the second stage in FIG. 5) formed in the middle of the trench 61 provided in the semiconductor substrate 31. As a result, the pixel isolation part 32 can be formed with high accuracy, and consequently, the characteristics of the pixel 21 can be improved.

Incidentally, the pixel isolation part 32 can adopt a configuration in which a metal such as tungsten, aluminum, or silver is deposited in place of the high-dielectric-constant film 46, or can adopt a configuration in which a metal such as tungsten or copper is embedded in place in place of the polysilicon layer 44.

### <Configuration Example of Electronic Device>

The imaging element 11 as described above can be applied to various electronic devices such as an imaging system such as a digital still camera or a digital video camera, a cellular phone having an imaging function, or other devices having an imaging function.

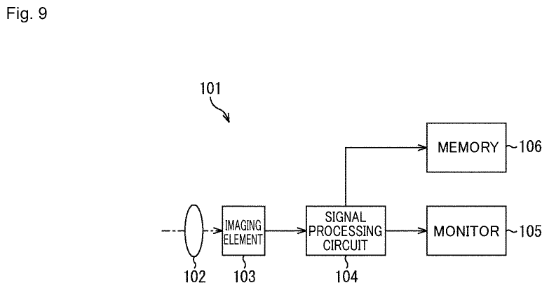

FIG. 9 is a block diagram of configuration example of an imaging device to be mounted in an electronic device.

As illustrated in FIG. 9, an imaging device 101 includes an optical system 102, an imaging element 103, a signal processing circuit 104, a monitor 105, and a memory 106, and is capable of capturing still images and moving images.

The optical system 102 includes one or a plurality of lenses, guides an image light (incident light) from a subject to the imaging element 103, and forms an image on the light-receiving surface of the imaging element 103.

As the imaging element 103, the above-described imaging element 11 is applied. In the imaging element 103, electrons are accumulated for a certain period of time according to the image formed on the light-receiving surface via the optical system 102. Then, a signal corresponding to the electrons accumulated in the imaging element 103 is supplied to the signal processing circuit 104.

The signal processing circuit 104 carries out various types of signal processing to pixel signals outputted from the imaging element 103. The image (image data) obtained by the signal processing carried out by the signal processing circuit 104 is supplied to the monitor 105 for display, or supplied to the memory 106 for storage (recording).

The imaging device 101 thus configured can, for example, capture images with better image quality by applying the imaging element 11 described above.

### <Usage Example of Image Sensor>

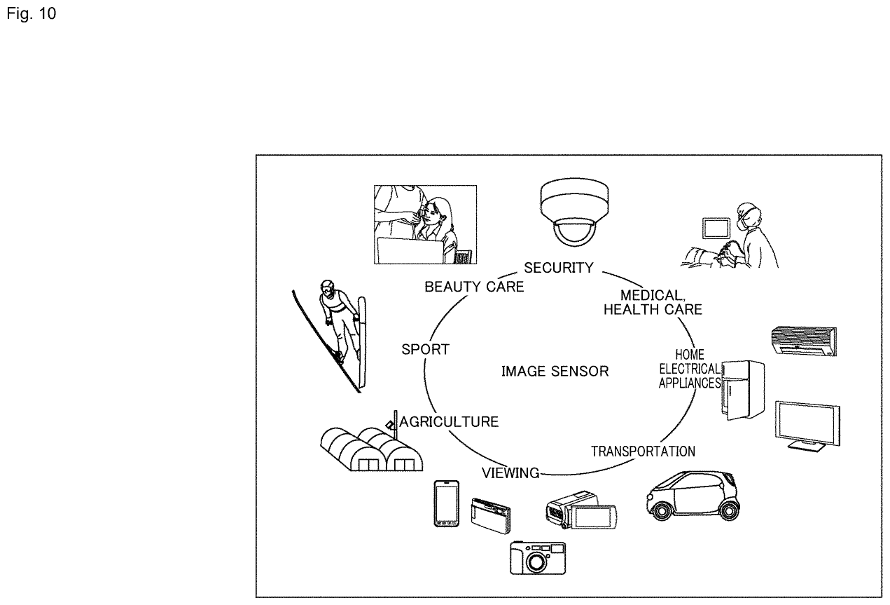

FIG. 10 is a diagram illustrating usage examples of how the above-described image sensor (imaging element) is used.

The above-described image sensor can be used, for example, in various cases for sensing light such as visible light, infrared light, ultraviolet light, or X-ray, in the following manner.

Apparatuses for photographing images to be used for applications for viewing such as a digital camera and a mobile device with a camera function

Apparatuses for applications in transportation such as a vehicle-mounted sensor that photographs the front, the rear, a periphery, an interior, or the like of an automobile for purposes of safe driving including automated braking, or the like, recognition of a state of a driver, and the like, a monitoring camera that monitors traveling vehicles or a road, a ranging sensor that measures distances between vehicles, and the like

Apparatuses to be used in home electrical appliances such as a TV, a refrigerator, and an air conditioner which photograph a gesture made by a user and perform device operation in accordance with the gesture

Apparatuses for applications in medical care and healthcare such as an endoscope and an apparatus that performs angiography by receiving infrared light

Apparatuses for applications in security such as a surveillance camera for crime-prevention applications and a camera for person authentication applications

Apparatuses for applications in beauty care such as a skin measuring device that photographs skin and a microscope that photographs the scalp

Apparatuses for applications in sports such as an action camera and a wearable camera for sports applications

Apparatuses for applications in agriculture such as a camera for monitoring a state of a field or crops

### <Configuration Combination Examples>

Incidentally, the present technology can also have the following configurations.

(1)

A solid-state imaging element, including:
a semiconductor substrate having a first surface serving as a light incident surface, and a second surface on an opposite side to the first surface;
a first photoelectric conversion unit provided in the semiconductor substrate;
a second photoelectric conversion unit provided adjacent to the first photoelectric conversion unit; and
a pixel isolation part provided between the first photoelectric conversion unit and the second photoelectric conversion unit,
in which
the pixel isolation part has a stacked structure in which a first layer, a second layer, and a third layer are stacked sequentially from the first surface side in a cross-sectional view, and
the second layer has a shape in which width thereof is different between the first layer side and the third layer side in a cross-sectional view.
   (2)

The solid-state imaging element according to (1), in which
the second layer is formed in a self-aligned manner at a predetermined position in the in-plane direction and the depth direction of the semiconductor substrate by utilizing a step portion formed in the middle of a trench provided in the semiconductor substrate.
   (3)

The solid-state imaging element according to (1) or (2), in which
the second layer is constituted of a semiconductor of the same conductivity type as that of a well of the semiconductor substrate, and
connection parts electrically connected to the semiconductor substrate are provided on both side surfaces of the second layer in a cross-sectional view.
   (4)

The solid-state imaging element according to (3), in which
the second layer is constituted of single crystal silicon formed by epitaxial growth from the connection parts present on both side surfaces of a trench in the middle of the trench provided on a silicon substrate that is the semiconductor substrate.
   (5)

The solid-state imaging element according to any of (1) to (4), in which the second layer has a cross-sectional shape in which the first layer side is narrow and the third layer side is wide, and an insulating film is provided on each of both opposite side surfaces of the wide portion.

(6)

The solid-state imaging element according to (5), in which
the insulating film is also provided between the second layer and the third layer, and is also provided on both side surfaces of the third layer, and
a polysilicon layer and a first insulating layer are stacked via the insulating film so as to constitute the third layer.
   (7)

The solid-state imaging element according to (6), in which
a high-dielectric-constant film is provided between the first layer and the second layer and on both side surfaces of the first layer, and
a second insulating layer is stacked via the high-dielectric-constant film so as to constitute the first layer.
   (8)

The solid-state imaging element according to (7), in which
in the semiconductor substrate that is a side surface of the pixel isolation part, side surfaces in a region of the first layer and the second layer, and a region where the polysilicon layer is provided of the third layer are doped with impurities.
   (9)

A method for manufacturing a solid-state imaging element, the element including:
a semiconductor substrate having a first surface serving as a light incident surface, and a second surface on an opposite side to the first surface;
a first photoelectric conversion unit provided in the semiconductor substrate;
a second photoelectric conversion unit provided adjacent to the first photoelectric conversion unit; and
a pixel isolation part provided between the first photoelectric conversion unit and the second photoelectric conversion unit,
in which
the pixel isolation part has a stacked structure in which a first layer, a second layer, and a third layer are stacked sequentially from the first surface side in a cross-sectional view, and
the second layer has a shape in which width thereof is different between the first layer side and the third layer side in a cross-sectional view,
the method including
forming the second layer in a self-aligned manner at a predetermined position in the in-plane direction and the depth direction of the semiconductor substrate using a step portion formed in the middle of a trench provided in the semiconductor substrate.
   (10)

An electronic device including a solid-state imaging element, the element including:
a semiconductor layer having a first surface serving as a light incident surface and a second surface on an opposite side to the first surface;
a first photoelectric conversion unit provided in the semiconductor substrate;
a second photoelectric conversion unit provided adjacent to the first photoelectric conversion unit; and
a pixel isolation part provided between the first photoelectric conversion unit and the second photoelectric conversion unit,
in which
the pixel isolation part has a stacked structure in which a first layer, a second layer, and a third layer are stacked sequentially from the first surface side in a cross-sectional view, and
the second layer has a shape in which width thereof is different between the first layer side and the third layer side in a cross-sectional view.

Incidentally, the present embodiments are not limited to the above-described embodiments and can be changed in various manners within the scope not departing from the gist of the present disclosure. Moreover, the effects described in the present description are merely examples and are not limited, and other effects may also be present.

### REFERENCE SIGNS LIST

11 Imaging element
21 Pixels
22 Sensor layer
23 Wiring layer
24 On-chip lens layer
25 Logic substrate
31 Semiconductor substrate
32 Pixel isolation part
33 Isolation part
34 Gate electrode
35 Contact electrode
36 Insulating film
37 Contact electrode
38 Microlens
41 Connection layer
42 connection part
43 Insulating film
44 Polysilicon layer
45 First insulating layer
46 High-dielectric-constant film
47 Second insulating layer
51 SiN film
52 SiO layer
53 Polysilicon film
54 SiN film
55 and 56 SiO films
57 Bottom surface layer
61 Trench
62 Cavity
63 Trench

1. A solid-state imaging device comprising:
a semiconductor substrate having a first surface serving as a light incident surface and a second surface on an opposite side to the first surface;
a first photoelectric conversion unit provided in the semiconductor substrate;
a second photoelectric conversion unit provided adjacent to the first photoelectric conversion unit; and
a pixel isolation part provided between the first photoelectric conversion unit and the second photoelectric conversion unit,
wherein
the pixel isolation part has a stacked structure in which a first layer, a second layer, and a third layer are stacked sequentially from the first surface side in a cross-sectional view, and
the second layer has a shape in which width thereof is different between the first layer side and the third layer side in a cross-sectional view.

2. The solid-state imaging element according to claim 1, wherein
the second layer is formed in a self-aligned manner at a predetermined position in an in-plane direction and a depth direction of the semiconductor substrate by utilizing a step portion formed in a middle of a trench provided in the semiconductor substrate.

3. The solid-state imaging element according to claim 1, wherein
the second layer is constituted of a semiconductor of the same conductivity type as that of a well of the semiconductor substrate, and
connection parts electrically connected to the semiconductor substrate are provided on both side surfaces of the second layer in a cross-sectional view.

4. The solid-state imaging element according to claim 3, wherein
the second layer is constituted of single crystal silicon formed by epitaxial growth from the connection parts present on both side surfaces of a trench in the middle of the trench provided on a silicon substrate that is the semiconductor substrate.

5. The solid-state imaging element according to claim 1, wherein
the second layer has a cross-sectional shape in which the first layer side is narrow and the third layer side is wide, and an insulating film is provided on each of both opposite side surfaces of the wide portion.

6. The solid-state imaging element according to claim 5, wherein
the insulating film is provided between the second layer and the third layer, and is also provided on both side surfaces of the third layer, and
a polysilicon layer and a first insulating layer are stacked via the insulating film so as to constitute the third layer.

7. The solid-state imaging element according to claim 6, wherein
a high-dielectric-constant film is provided between the first layer and the second layer and on both side surfaces of the first layer, and
a second insulating layer is stacked via the high-dielectric-constant film so as to constitute the first layer.

8. The solid-state imaging element according to claim 7, wherein
in the semiconductor substrate that is a side surface of the pixel isolation part, side surfaces in a region of the first layer and the second layer, and a region where the polysilicon layer is provided of the third layer are doped with impurities.

9. A method for manufacturing a solid-state imaging element, the element including:
a semiconductor substrate having a first surface serving as a light incident surface and a second surface on an opposite side to the first surface;
a first photoelectric conversion unit provided in the semiconductor substrate;
a second photoelectric conversion unit provided adjacent to the first photoelectric conversion unit; and
a pixel isolation part provided between the first photoelectric conversion unit and the second photoelectric conversion unit,
the pixel isolation part having a stacked structure in which a first layer, a second layer, and a third layer are stacked sequentially from the first surface side in a cross-sectional view, and
the second layer having a shape in which width thereof is different between the first layer side and the third layer side in a cross-sectional view,
the method comprising:
forming the second layer in a self-aligned manner at a predetermined position in an in-plane direction and a depth direction of the semiconductor substrate by using a step portion formed in a middle of a trench provided in the semiconductor substrate.

10. An electronic device, comprising a solid-state imaging element, the solid-state imaging element including:
a semiconductor substrate having a first surface serving as a light incident surface and a second surface on an opposite side to the first surface;
a first photoelectric conversion unit provided ins the semiconductor substrate;
a second photoelectric conversion unit provided adjacent to the first photoelectric conversion unit; and
a pixel isolation part provided between the first photoelectric conversion unit and the second photoelectric conversion unit,
wherein
the pixel isolation part has a stacked structure in which a first layer, a second layer, and a third layer are stacked sequentially from the first surface side in a cross-sectional view, and
the second layer has a shape in which width thereof is different between the first layer side and the third layer side in a cross-sectional view.
